(19) United States
(12) Patent Application Publication
(10) Pub. No.: US 2025/0154370 A1
(43) Pub. Date: May 15, 2025

(54) SOLID STATE ADDITIVES WITH CO-SOLVENT EFFECT TO INCREASE POLYMER SOLAR CELL INK AND DEVICE SHELF LIFE

(71) Applicant: North Carolina State University, Raleigh, NC (US)

(72) Inventors: Harald Werner Ade, Cary, NC (US); Zhen Wang, Sheung Wan (HK); Zhengxing Peng, Richmond, CA (US)

(21) Appl. No.: 18/943,788

(22) Filed: Nov. 11, 2024

Related U.S. Application Data
(60) Provisional application No. 63/548,161, filed on Nov. 10, 2023.

(51) Int. Cl. C09D 11/52; H10K 30/50; H10K 85/20

(52) U.S. Cl. CPC C09D 11/52; H10K 30/50; H10K 85/215

(57) ABSTRACT

A polymer solar cell ink for organic solar cell (OSC) devices is provided. The polymer solar cell ink includes at least one solid state additive. The polymer solar cell ink further includes a donor polymer. The polymer solar cell ink further includes a nonfullerene acceptor (NFA).

### PRIORITY CLAIM

This application claims the priority benefit of U.S. Provisional Patent Application Ser. No. 63/548,161 filed Nov. 10, 2023, the disclosure of which is incorporated herein by reference in its entirety.

### GOVERNMENT INTEREST

This invention was made with government support under grant numbers N00014-20-1-2155 and N6833521C0350 awarded by the Office of Naval Research. The government has certain rights in the invention.

### TECHNICAL FIELD

The subject matter described herein relates to organic solar cells. More particularly, the subject matter described herein relates to solid state additives with co-solvent effect to increase polymer solar cell ink and device shelf life and methods for preparing the same.

### BACKGROUND

Organic solar cells (OSCs) with ink-processed photoactive layers have recently achieved power conversion efficiencies (PCEs) of over 18-19% in laboratories, after decades of effort to design new materials and optimize device engineering and processing. Further optimization of molecular modifications and ternary blending strategy is still intensively ongoing and pushing the efficiencies towards the Shockley-Queisser limit. Reports of large-area modules on rigid and flexible substrates are making it possible to be industrially manufactured, owing to their excellent ability to be ink-processed. However, critical challenges of stability still remain to be overcome for their commercialization. Without decent stability and long enough lifetime with consistent performance, OSC products are still too immature to be utilized in and applied to our real life.

Accordingly, there exists a need for a polymer solar cell ink with a higher stability that results in a slower degradation and a longer shelf life.

### SUMMARY

An example polymer solar cell ink for organic solar cell (OSC) devices includes at least one solid state additive, a donor polymer; and a nonfullerene acceptor (NFA).

According to another aspect of the polymer solar cell ink, the at least one solid state additive includes at least one PCBM.

According to another aspect of the polymer solar cell ink, the at least one PCBM includes PC₆₁BM.

According to another aspect of the polymer solar cell ink, the at least one PCBM includes PC₇₁BM.

According to another aspect of the polymer solar cell ink, the at least one PCBM includes a plurality of PCBM variants.

According to another aspect of the polymer solar cell ink, the donor polymer includes D18-CI and the NFA includes Y6.

According to another aspect of the polymer solar cell ink, the ink has a ratio by weight of about 1:1.6:0.2 for D18-CI:Y6:PCBM.

According to another aspect of the polymer solar cell ink, the donor polymer includes PM6 and the NFA includes Y6.

According to another aspect of the polymer solar cell ink, the polymer solar cell ink maintains a higher electron percolation than a polymer solar cell ink without the at least one solid state additive.

According to another aspect of the subject matter described herein, an OSC device includes an active layer including the polymer solar cell ink.

An example method for preparing a polymer solar cell ink for organic solar cell (OSC) devices includes dissolving, at a temperature of about 50° C., at least one solid state additive in a donor polymer or a nonfullerene acceptor (NFA) to form a solid state additive mixture. The method further includes mixing the solid state additive mixture with the NFA or the donor polymer to form a ternary blend of the polymer solar cell ink.

According to another aspect of the method, the at least one solid state additive includes at least one PCBM.

According to another aspect of the method, the at least one PCBM includes PC₆₁BM.

According to another aspect of the method, the at least one PCBM includes PC₇₁BM.

According to another aspect of the method, the at least one PCBM includes a plurality of PCBM variants.

According to another aspect of the method, the donor polymer includes D18-CI and the NFA includes Y6.

According to another aspect of the method, the ternary blend has a ratio by weight of about 1:1.6:0.2 for D18-CI:Y6:PCBM.

According to another aspect of the method, the donor polymer includes

PM6 and the NFA includes Y6.

According to another aspect of the method, the polymer solar cell ink maintains a higher electron percolation than a polymer solar cell ink without the at least one solid state additive.

According to another aspect of the method, the method includes forming a film of the ternary blend of the polymer solar cell ink to form an active layer for an OSC device.

### BRIEF DESCRIPTION OF THE DRAWINGS

The subject matter described herein will now be explained with reference to the accompanying drawings of which:

FIGS. 1A-1G show molecular information and device performance. FIG. 1A shows molecular structures of D18-CI, Y6, PC₆₁BM and PC₇₁BM. FIG. 1B illustrates ink stored in a glass vial used in laboratories. FIG. 1C illustrates an example architecture of an OSC device. FIG. 1D is a graph showing normalized absorption of D18-CI, Y6, PC₆₁BM and PC₇₁BM. FIGS. 1E-1G show J-V curves of OSC devices based on D18-CI:Y6 (FIG. 1E), D18-CI:Y6:PC₆₁BM (FIG. 1F), and D18-CI:Y6:PC₇₁BM (FIG. 1G) blends with photoactive layers cast from fresh, 5-day-aged, and 20-day-aged inks;

FIGS. 2A-2D show molecular packing and morphology characterization. FIGS. 2A and 2B show 1D GIWAXS profiles of films based on D18-CI:Y6, D18-CI:Y6:PC₆₁BM and D18-CI:Y6:PC₇₁BM blends, cast from fresh, 5-day-aged, and 20-day-aged inks, along OOP (FIG. 2A) and IP (FIG. 2B) directions. FIG. 2C shows Lorentz-corrected thickness-normalized R-SoXS profiles of films based on D18-CI:Y6 cast from fresh, 5-day-aged, and 20-day-aged inks, acquired at 283.8 eV. FIG. 2D shows Long periods obtained from R-SoXS profiles of D18-CI:Y6, D18-CI:Y6:PC₆₁BM and D18-CI:Y6:PC₇₁BM blends as a function of ink aging days. The D18-CI:Y6 blends show two different long periods, both of which are showing an increasing trend when ink aged, while the ternaries are not;

FIGS. 3A-3D show thermodynamics characterization. FIG. 3A shows TOF-SIMS profiles of D18-CI/Y6 bilayer samples annealed at temperatures as indicated, tracking F-ion of the acceptor Y6. FIG. 3B shows simulated binodal curve of D18-CI:Y6 system along with the miscibility information (Y6 fraction Φ vs. temperature) measured with TOF-SIMS.

FIGS. 3C and 3D show mass-normalized TOF-SIMS profiles of D18-CI/PC₆₁BM (FIG. 3C) and D18-CI/PC₇₁BM (FIG. 3D) bilayers (nominal thicknesses of D18-CI and PCBMs are around 100 nm and 200 nm, respectively) solvent vapor annealed, tracking the S-ion of the polymer. In the reference profiles, normalized S-counts (representing D18-CI) is 1, and in the SVA profiles, normalized S-counts is correlated to the fraction of D18-CI in the inter-diffused film. As can be seen, the D18-CI layer is swelled by the PCBMs after interdiffusion accelerated by SVA. It is fairly straightforward in this case to estimate the PCBM fractions by subtracting the S-counts of SVA profiles;

FIGS. 4A-4D show microscope images and UV-vis absorption spectra to determine compositions. FIGS. 4A and 4B show VLM images of Y6:PC₆₁BM (1:1 w/w; FIG. 4A), and Y6:PC₇₁BM (1:1 w/w, FIG. 4B) blend films, SVA with CB for 48 hours at room temperature. FIGS. 4C and 4D show UV-vis absorption spectra and fits of Y6:PC₆₁BM (FIG. 4C), and Y6:PC₇₁BM (FIG. 4D) blend films, SVA with CB for 48 hours at room temperature;

FIG. 5 is a flow chart illustrating and example method for preparing a polymer solar cell ink for organic solar cell (OSC) devices;

FIGS. 6A-6C show normalized UV-vis absorption spectra of D18-CI:Y6 (FIG. 6A), D18-CI:Y6:PC₆₁BM (FIG. 6B), and D18-CI:Y6:PC₇₁BM (FIG. 6C) blend films, cast from fresh, 5-day-aged, and 20-day aged inks;

FIGS. 7A and 7B shows 2D GIWAXS patters of neat D18-CI (FIG. 7A) and Y6 (FIG. 7B) films;

FIGS. 8A-8C show 2D GIWAXS patterns of D18-CI:Y6 binary blend films, cast from fresh (FIG. 8A), 5-day-aged (FIG. 8B), and 20-day-aged (FIG. 8C) inks;

FIGS. 9A-9C show 2D GIWAXS patterns of D18-CI:Y6:PC₆₁BM ternary blend films, cast from fresh (FIG. 9A), 5-day-aged (FIG. 9B), and 20-day-aged (FIG. 9C) inks;

FIGS. 10A-10C show 2D GIWAXS patterns of D18-CI:Y6:PC₇₁BM ternary blend films, cast from fresh (FIG. 10A), 5-day-aged (FIG. 10B), and 20-day-aged (FIG. 10C) inks;

FIGS. 11A and 11B show Lorentz-corrected thickness-normalized RSoXS profiles of films based on D18-CI:Y6:PC₆₁BM (FIG. 11A) and D18-CI:Y6:PC₇₁BM (FIG. 11B) blends, cast from fresh, 5-day-aged, and 20-day-aged ink, acquired at 283.8 eV;

FIGS. 12A-12C show Lognormal fit of Lorentz-corrected R-SoXS profiles of D18-CI:Y6 binary blend films, cast from fresh (FIG. 12A), 5-day-aged (FIG. 12B), and 20-day-aged (FIG. 12C) inks, acquired at 283.8 eV;

FIGS. 13A-13C show Lognormal fit of Lorentz-corrected R-SoXS profiles of D18-CI:Y6:PC₆₁BM ternary blend films, cast from fresh (FIG. 13A), 5-day-aged (FIG. 13B), and 20-day-aged (FIG. 13C) inks, acquired at 283.8 eV;

FIGS. 14A-14C show Lognormal fit of Lorentz-corrected R-SoXS profiles of D18-CI:Y6:PC₇₁BM ternary blend films, cast from fresh (FIG. 14A), 5-day-aged (FIG. 14B), and 20-day-aged (FIG. 14C) inks, acquired at 283.8 eV;

FIGS. 15A-15D show TOF-SIMS profiles for comparison. FIG. 15A shows TOF-SIMS profiles of D18-CI/Y6 bilayer samples annealed with CB vapor, tracking F-ion of the acceptor. FIG. 15B shows mass-normalized TOF-SIMS profiles of D18-CI/Perylene Red bilayer samples annealed with CB vapor, tracking CI-ion of the polymer. FIGS. 15C and 15D show mass-normalized TOF-SIMS profiles of D18-CI/PC₆₁BM (FIG. 15C) and D18-CI/PC₇₁BM (FIG. 15D) bilayers, solvent annealed, tracking S-ion of the polymer;

FIGS. 16A-16F show microscope images and UV-vis absorption spectra to determine compositions. FIGS. 16A-16C are VLM images of D18-CI:Y6 (FIG. 16A), D18-CI:PC₆₁BM (FIG. 16B), and D18-CI:PC₇₁BM (FIG. 16C) blend films, SVA with chlorobenzene for 48 hours. FIGS. 16D-16F show UV-vis absorption spectra of D18-CI:Y6 (FIG. 16D), D18-CI:PC₆₁BM (FIG. 16E), and D18-CI:PC₇₁BM (FIG. 16F) blend films, as cast and SVA with chlorobenzene for 48 hours;

FIGS. 17A-17D show microscope images and UV-vis absorption spectra to determine compositions. FIGS. 17A and 17B are VLM images of Y6:PC₆₁BM (1:1 w/w, FIG. 17A), and Y6:PC₇₁BM (1:1 w/w, FIG. 17B) blend films, SVA with chlorobenzene for 48 hours at −2° C. FIGS. 17C and 17D show UV-vis absorption spectra of Y6:PC₆₁BM (FIG. 17C), and Y6:PC₇₁BM (FIG. 17D) blend films, SVA with chlorobenzene for 48 hours at −2° C.;

FIG. 18 is a schematic diagram showing the molecular structure of Perylene Red; and

FIGS. 19A and 19B show J-V curves of PM6:Y6 (FIG. 19A) and PM6:Y6:PC₇₁BM (FIG. 19B) devices fabricated from fresh and aged inks.

### DETAILED DESCRIPTION

### Introduction

The subject matter described herein includes solid state additives with co-solvent effect to increase polymer solar cell ink and device shelf life and methods for preparing the same. Instabilities of OSCs stem from a number of factors, such as oxygen/moisture sensitivity, surface-assisted photoreaction, electrode/interlayer degradation; and morphology failure. With proper device engineering and encapsulation, issues from the outside and interfaces can be significantly suppressed. One of the intrinsic instabilities that needs to be understood and controlled is the morphology stability. Ghasemi et al. have developed the Ade-O'Connor-Ghasemi interaction-diffusion framework for predicting OSC stability of binaries and revealed that the thermodynamically most unstable, hypo-miscible systems are the most kinetically stabilized. The use of a ternary component with high miscibility to maintain charge percolation (a system referred as hyper-miscible) and high glass transition temperature (for a given molecule size) to slow down the diffusion in order to achieve an ultra-stable morphology is conceptually desirable but faces practical hurdles as these demands are not favored thermodynamically.

Studies have concentrated on the stability of practical OSC devices, while rarely reporting about the pre-fabrication requirements for commercialization and their underlying molecular interactions. Generally, when fabricating the devices, freshly dissolved solutions/inks are made and used to spin-cast the photoactive layers. OSCs made with aged inks usually exhibit poorer performance than that made from fresh inks, and some aged inks are even unable to be restored and reused after only a few hours. The molecules in the inks can pre-aggregate as solutions cool for materials that show strong temperature dependent aggregation, which plays a critical role in the film molecular packing and morphology as solvent evaporates during processing and the concentration increases. Such aggregation depends on the molecular self-interaction and the interaction with the solvent. In principle, any ink made by heating the solution is likely subjected to pre-aggregation that limits ink shelf life. For future fabrication and manufacture and even for now in laboratories, this current necessity of using fresh inks is leading to significant waste of photovoltaic materials or contributes to reproducibility issues and narrow fabrication windows. Due to reduced solubility, aging is particularly rapid from non-chlorinated solvents such as o-xylene explored to upscale printing with an acceptable environmental footprint. Thus, understanding the reason of ink degradation and aging and finding a way to slow it down or prevent it altogether is very important to reducing engineering bottlenecks to industrial production.

The subject matter herein describes polymer solar cell inks for OSCs with extended shelf life due to their slower aging and degradation resulting from at least one solid state additive. The solid state additive selected has a high miscibility with the donor polymer in the ink and possibly even with the NFA in the ink. Examples of binary polymer solar cell inks to which at least one solid state additive is added to form ternary polymer cell inks include D18-CI:Y6 and PM6:Y6, wherein D18-CI and PM6 are example donor polymers and Y6 is an example NFA. The at least one solid state additive can be hydrophobic, have a high surface energy, and/or be photoelectrically active. The at least one solid state additive can include one or more variants of PCBM, such as PC₆₁BM and/or PC₇₁BM.

The following includes example preparations and testing procedures of polymer solar cell ink for OSCs:

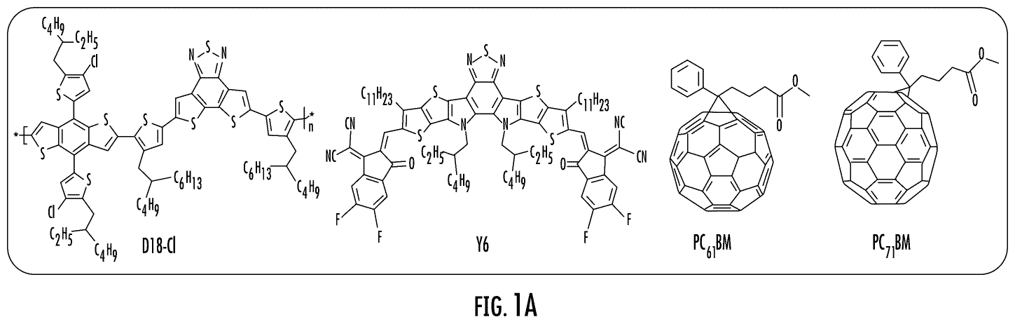

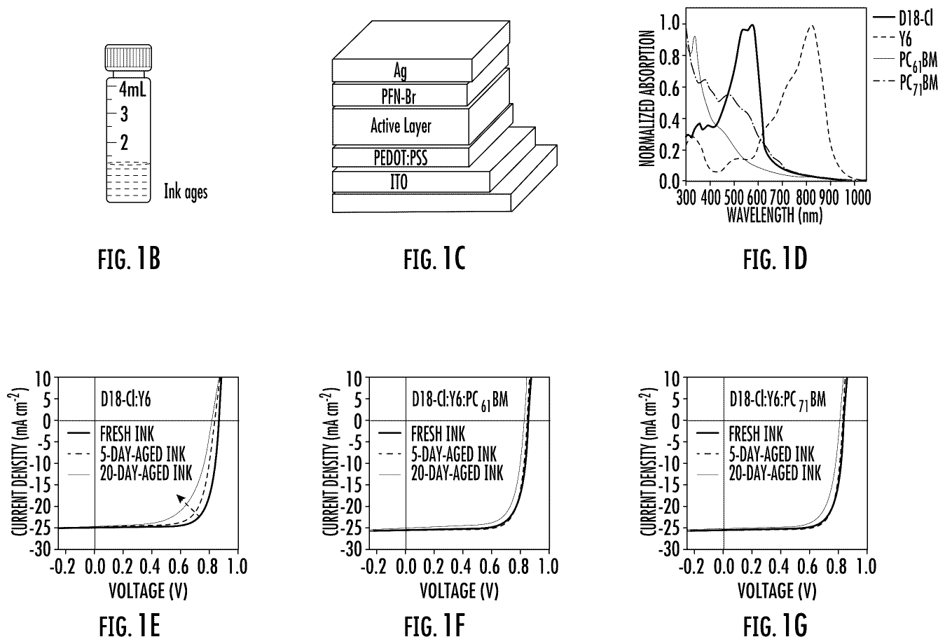

We report thermodynamic properties of active materials as they relate to ink aging. We start by unveiling the ink aging of D18-CI:Y6 blend and demonstrate an effective approach to suppress the observed significant ink aging by employing third components (PC₆₁BM or PC₇₁BM) that we show to have high miscibility with the polymer and Y6. Molecular structures of these compounds can be found in FIG. 1A. The D18-CI:Y6 binary system shows a decreasing fill factor (FF) as the ink ages. Devices made from fresh ink exhibit an FF of 75.2%, and those made from 5-day-aged and 20-day-aged inks show poor FFs of 70.5% and 61.1%, respectively. With the PCBMs as third components, the ternary devices made from 20-day aged inks still show decent FFs of over 70%. We have employed molecular packing, morphology and thermodynamic characterizations to figure out the reason. X-ray scattering experiments reveal that the molecular packing of binary and ternary films cast from fresh and aged inks are very similar. In contrast, the long period (related to domain size) of the films is found to be larger when cast from aged inks for the binary blend while not for the ternary blends. The miscibility of D18-CI:Y6 is determined to be small (few %) at room temperature. In contrast, the PCBMs exhibit quite large miscibilities (>50%) with the D18-CI and Y6. In contrast, perylene red has low miscibility with D18-CI and cannot suppress the ink aging. We have attributed the deceleration of ink aging to PCBMs suppressing the pre-aggregation of the polymer and likely Y6 in inks. This suppression of ink aging by introducing a highly miscible acceptor also works for the PM6:Y6 system, as observed during an initial assessment of the generality of our findings. An added synergistic benefit is that the high miscibility of the fullerenes maintains percolation pathways for electrons and also stabilizes devices. Our approach of introducing a highly miscible third component to suppress the ink aging as well as maintain the percolation is of significant importance to promote the scale-up of low-cost ink-processed polymer solar cells and hence a step to their commercialization.

### Results and Discussion

We explored ink-aging based-on the high efficiency D18-CI:Y6 binary and ternary blends with two PCBMs (PC₆₁BM and PC₇₁BM). The illustrations of inks used and the device architecture are shown in FIGS. 1B and 1C, respectively. Details of fabrication recipe can be found in the EXPERIMENTAL PROCEDURES. FIG. 1D shows the normalized ultraviolet-visible (UV-vis) absorption of D18-CI, Y6 and PCBM films. The binary solar cells based on D18-CI:Y6 from fresh inks exhibit an average PCE of 16.18% with an open-circuit voltage (VOC) of 0.849, a short-circuit current density (JSC) of 25.33 mA cm-2, and an FF of 75.2%. While after 5 days, the very same batch of ink gives a PCE of 15.01% with a VOC of 0.84 and a decreased FF of 70.5%. Aged for 20 days, devices fabricated from the ink perform a PCE of 12.37% (which is only 76% of that made from fresh ink), with a lower VOC of 0.82 and a poor FF of 61.1%. Clearly the binary ink can age quite pronounced within only a few days, even when the vial is sealed properly and stored in the dark and in a nitrogen atmosphere.

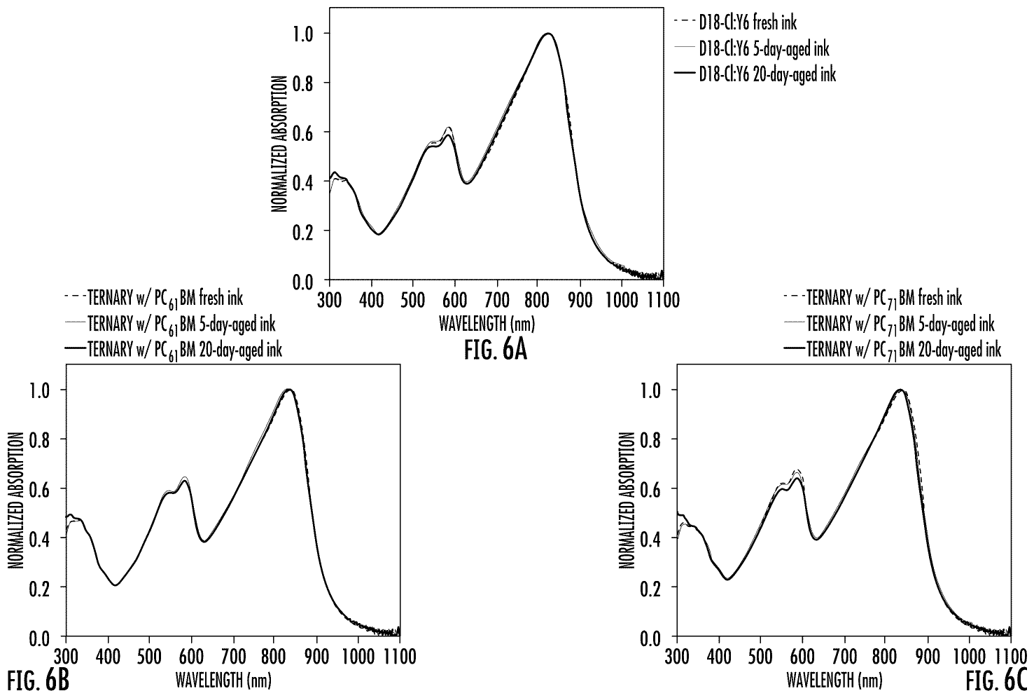

As PCBMs can be highly miscible with some donor polymer that improves the performance and stability of many other binary nonfullerene systems, in large part by maintaining percolation (electron pathways) and hence suppress the degradation that comes from over-purification of mixed disorder domains, we employed PCBM as third components to investigate the ink aging and relations to miscibility. The ternary solar cells based on D18-CI:Y6:PC₆₁BM from fresh inks exhibit a slightly improved PCE of 16.54%, with a VOC of 0.849, a JSC of 25.43 mA cm-2, and an FF of 76.6%. Importantly, the ternary solar cells fabricated from 5-day-aged ink still give a PCE of 16.15%, with a VOC of 0.845, a JSC of 25.53 mA cm-2, and an FF of 74.8%. Even the devices made from 20-day-aged ink perform with an efficiency of 15.02%, with a VOC of 0.831, a JSC of 25.20 mA cm-2, and an FF of 71.7%. In the case of PC₇₁BM, the trend is quite similar. The current density-voltage (J-V) curves corresponding to the binary and ternary devices are shown in FIGS. 1E-1G, and the photovoltaic parameters are summarized in Table 1, below. It seems that though the ternary inks with PCBMs also age, but this aging is significantly reduced compared to the binary one. After 20 days, the aged ternary inks can still give FFs of over 70%, while the binary one already decreased to ˜60%. FIGS. 6A-6C show the normalized UV-vis absorption spectra of D18-CI:Y6, D18-CI:Y6:PC₆₁BM, and D18-CI:Y6:PC₇₁BM blend films, cast from fresh, 5-day-aged and 20-day-aged inks. No pronounced differences can be distinguished from the fresh inks and 5-day-aged inks, which is likely because that the aging has limited impact to the molecular packing and optical, local aggregation effects. But after 20-days-aging, the absorption intensities corresponding to D18-CI become relatively smaller in all three systems.

TABLE 1
Summary of Photovoltaic Performance of Devices
Fabricated From Fresh and Aged Inks

| | | J_{SC} | | PCE_{avg} | PCEₘₐₓ |
|---|---|---|---|---|---|
| Blends | V_{OC} (V) | (mA cm⁻²) | FF (%) | (%) | (%) |
| D18-CI:Y6 | 0.849 ± 0.009 | 25.33 ± 0.17 | 75.2 ± 0.5 | 16.18 ± 0.2 | 16.62 |
| Fresh ink | | | | | |
| D18-CI:Y6 | 0.840 ± 0.003 | 25.32 ± 0.21 | 70.5 ± 0.6 | 15.01 ± 0.18 | 15.25 |
| 5-day-aged ink | | | | | |
| D18-CI:Y6 | 0.820 ± 0.010 | 24.66 ± 0.35 | 61.1 ± 1.2 | 12.37 ± 0.44 | 12.87 |
| 20-day-aged ink | | | | | |
| D18-CI:Y6:PC₆₁BM | 0.849 ± 0.005 | 25.43 ± 0.32 | 76.6 ± 0.8 | 16.54 ± 0.36 | 17.15 |
| Fresh ink | | | | | |
| D18-CI:Y6:PC₆₁BM | 0.845 ± 0.005 | 25.53 ± 0.30 | 74.8 ± 0.3 | 16.15 ± 0.23 | 16.56 |
| 5-day-aged ink | | | | | |
| D18-CI:Y6:PC₆₁BM | 0.831 ± 0.007 | 25.20 ± 0.20 | 71.7 ± 0.6 | 15.02 ± 0.20 | 15.21 |
| 20-day-aged ink | | | | | |
| D18-CI:Y6:PC₇₁BM | 0.836 ± 0.003 | 25.31 ± 0.46 | 77.2 ± 0.3 | 16.33 ± 0.31 | 16.76 |
| Fresh ink | | | | | |
| D18-CI:Y6:PC₇₁BM | 0.845 ± 0.009 | 25.68 ± 0.18 | 74.7 ± 0.1 | 16.23 ± 0.30 | 16.62 |
| 5-day-aged ink | | | | | |
| D18-CI:Y6:PC₇₁BM | 0.826 ± 0.003 | 25.09 ± 0.30 | 70.9 ± 0.6 | 14.70 ± 0.24 | 14.98 |
| 20-day-aged ink | | | | | |

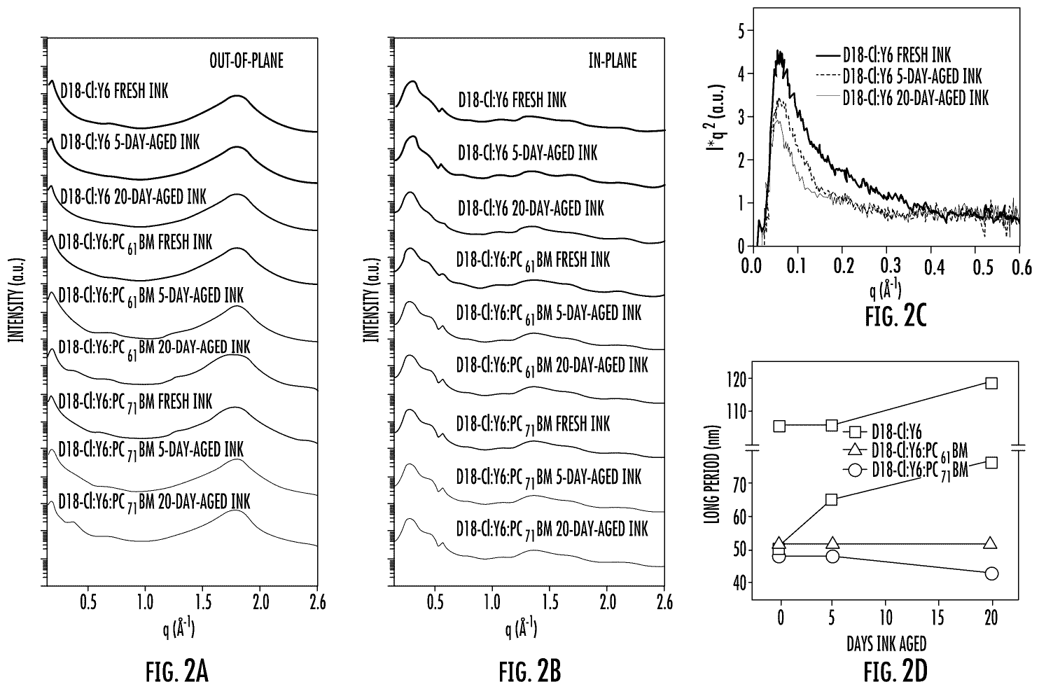

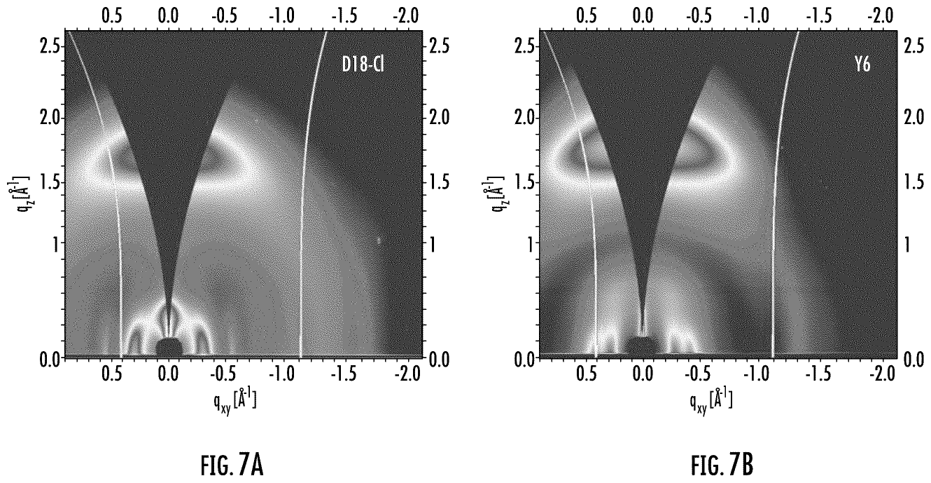

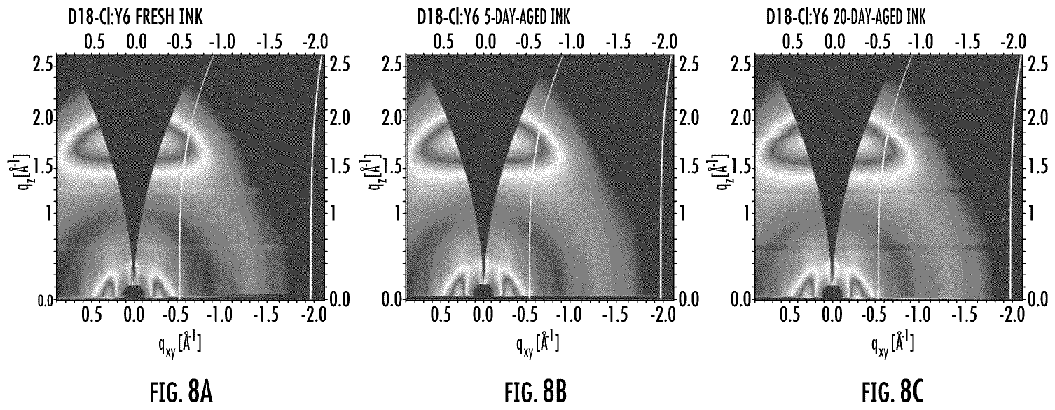

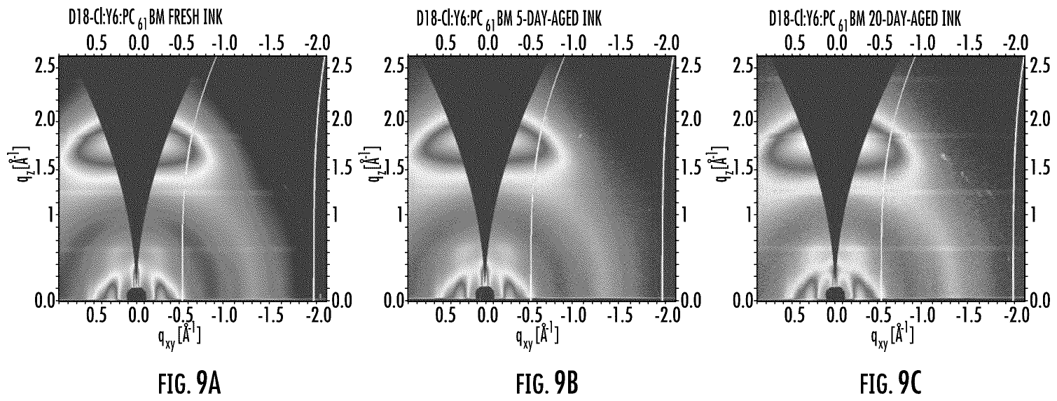

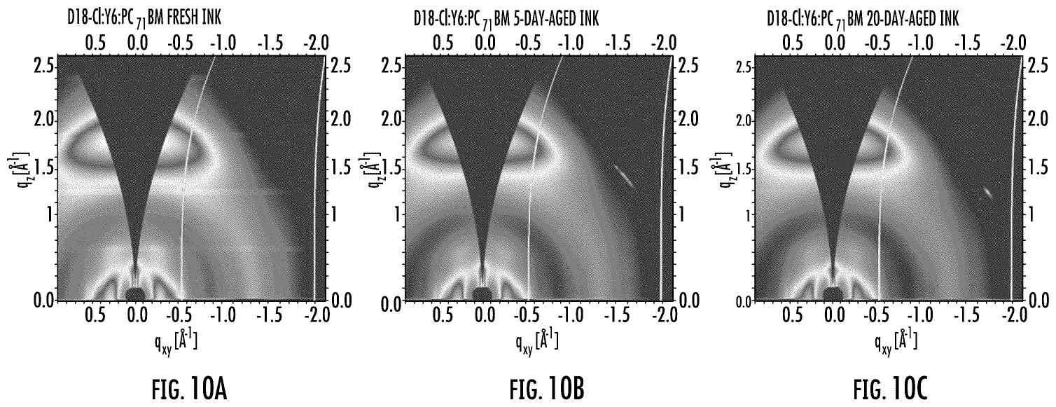

To understand the differences of devices made from fresh and aged inks, we have conducted grazing incidence wide angle X-ray scattering (GIWAXS) and resonant soft X-ray scattering (R-SoXS) to probe the molecular packing and in-plane morphology of the photoactive layers. FIGS. 7a and 7B show the 2D GIWAXS patterns of neat D18-CI and Y6 films. The D18-CI also shows the (001) diffraction peaks as D18 exhibits strong chain extension. FIGS. 8A-8C, 9A-9C, and 10A-10C display the 2D GIWAXS patterns of binary and ternary blend films based on D18-CI:Y6, D18-CI:Y6:PC₆₁BM and D18-CI:Y6:PC₇₁BM, respectively, cast from fresh, 5-day-aged and 20-day-aged inks. The corresponding 1D profiles along out-of-plane (OOP) and in-plane (IP) directions are shown in FIGS. 2A and 2B. The related information of coherence lengths (LC) and g parameters are calculated and summarized in Table 2, below. The GIWAXS data analysis shows that the molecular packing and quality of ordering are not changing much relative to fresh inks when films are cast from aged inks, which is consistent with the UV-vis absorption spectra.

TABLE 2
Summary of GIWAXS results (out-of-plane direction) for D18-
CI:Y6, D18-CI:Y6:PC₆₁BM, and D18-CI:Y6:PC₇₁BM blend films,
cast from fresh, 5-day-aged and 20-day-aged inks, respectively.

| | | |
|---|---|---|
| Peaks | (010) D18-CI | (010)′ Y6 |

D18-CI:Y6 fresh ink

| | | |
|---|---|---|
| q (Å⁻¹) | 1.69 | 1.79 |
| L_{C} (Å) | 13.8 | 23.6 |
| g (%) | 13.2 | 10.4 |

D18-CI:Y6 5-day-aged ink

| | | |
|---|---|---|
| q (Å⁻¹) | 1.69 | 1.78 |
| L_{C} (Å) | 12.6 | 23.6 |
| g (%) | 13.9 | 10.4 |

D18-CI:Y6 20-day-aged ink

| | | |
|---|---|---|
| q (Å⁻¹) | 1.69 | 1.77 |
| L_{C} (Å) | 11.8 | 25.7 |
| g (%) | 14.3 | 9.9 |

D18-CI:Y6:PC₆₁BM fresh ink

| | | |
|---|---|---|
| q (Å⁻¹) | 1.69 | 1.78 |
| L_{C} (Å) | 13.1 | 25.7 |
| g (%) | 13.6 | 10.0 |

D18-CI:Y6:PC₆₁BM 5-day-aged ink

| | | |
|---|---|---|
| q (Å⁻¹) | 1.69 | 1.80 |
| L_{C} (Å) | 13.1 | 25.7 |
| g (%) | 13.6 | 10.0 |

D18-CI:Y6:PC₆₁BM 20-day-aged ink

| | | |
|---|---|---|
| q (Å⁻¹) | 1.69 | 1.78 |
| L_{C} (Å) | 13.5 | 24.6 |
| g (%) | 13.4 | 10.2 |

D18-CI:Y6:PC₇₁BM fresh ink

| | | |
|---|---|---|
| q (Å⁻¹) | 1.69 | 1.79 |
| L_{C} (Å) | 12.6 | 25.7 |
| g (%) | 13.9 | 10.0 |

D18-CI:Y6:PC₇₁BM 5-day-aged ink

| | | |
|---|---|---|
| q (Å⁻¹) | 1.69 | 1.79 |
| L_{C} (Å) | 12.8 | 25.7 |
| g (%) | 13.7 | 10.0 |

D18-CI:Y6:PC₇₁BM 20-day-aged ink

| | | |
|---|---|---|
| q (Å⁻¹) | 1.69 | 1.79 |
| L_{C} (Å) | 12.6 | 26.9 |
| g (%) | 13.9 | 9.8 |

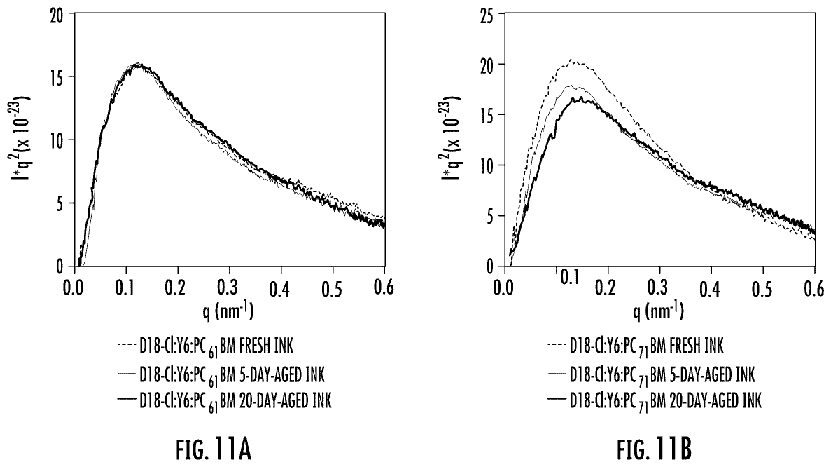

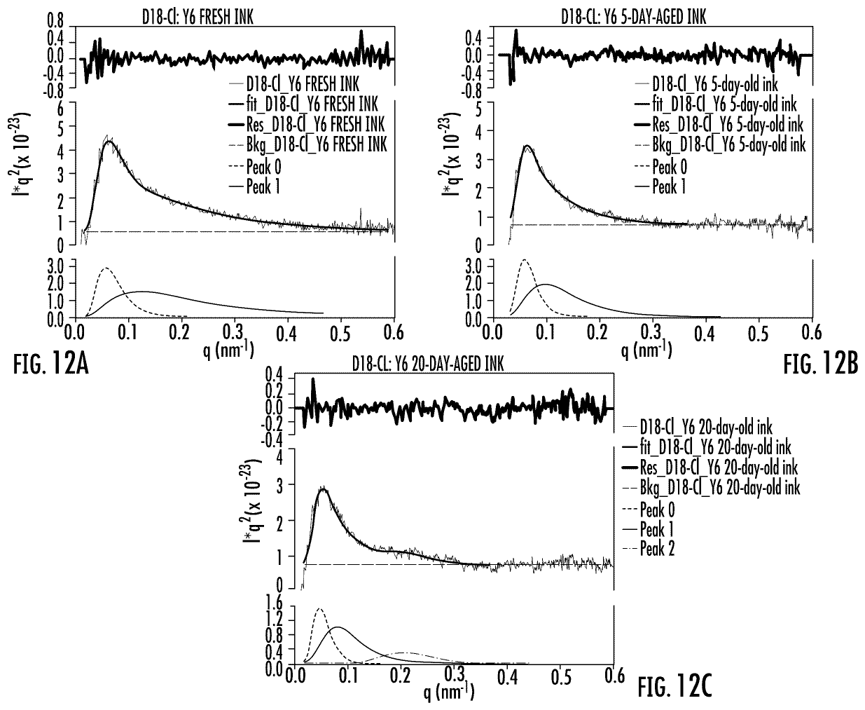

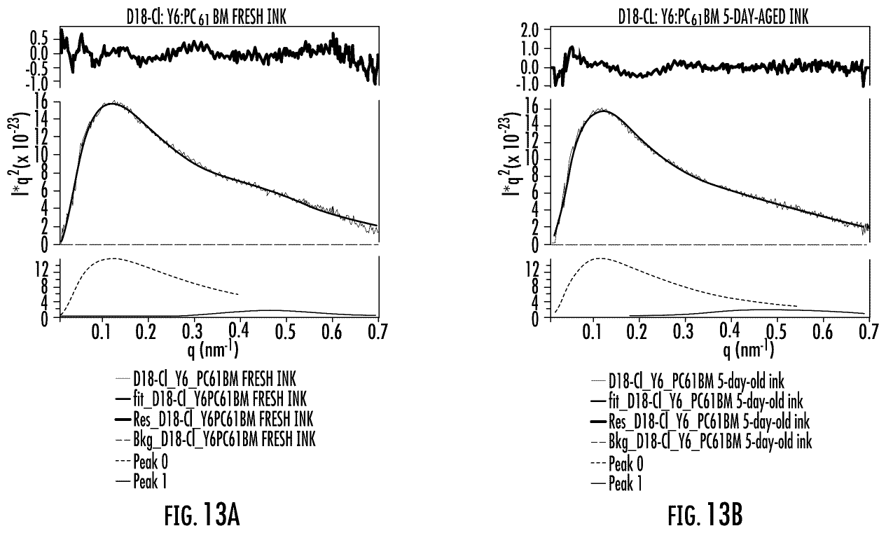

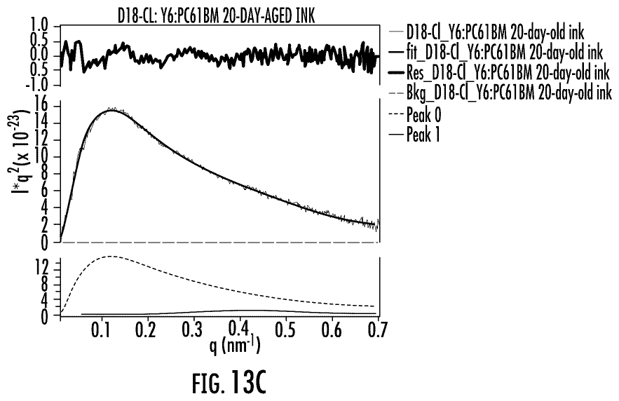

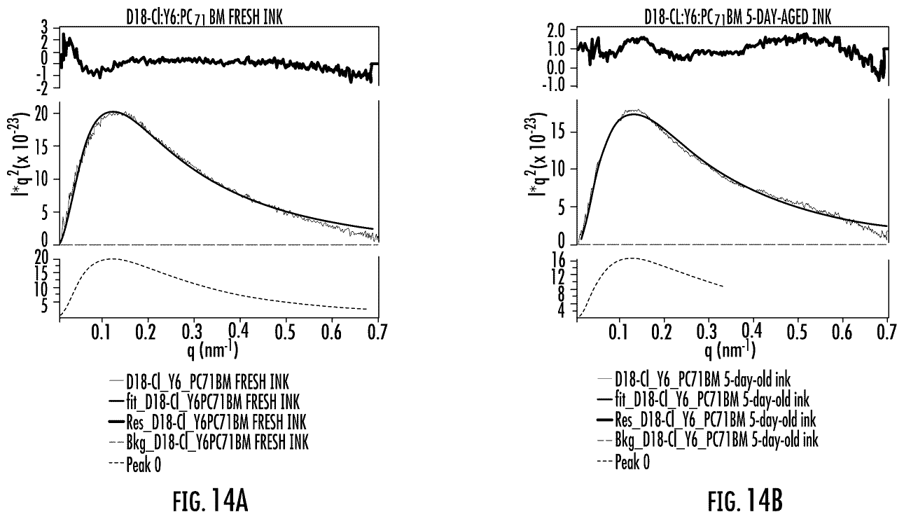

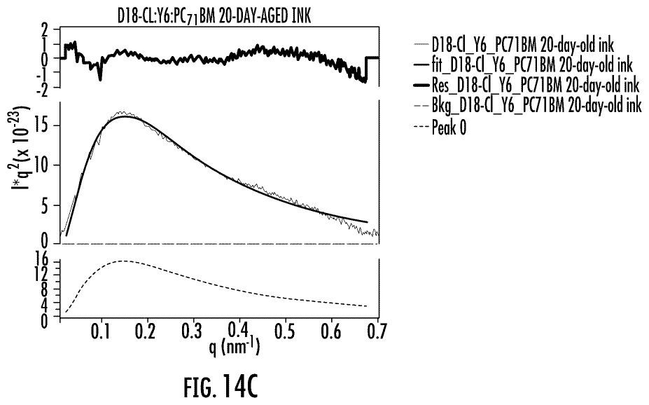

The R-SoXS profiles of the D18-CI systems show strong fluorescence backgrounds, especially with X-ray energies above the C is absorption onset. We correct this unfavorable background and extract the long period information from the diffraction features of R-SoXS profiles acquired at low energies. The Lorentz-corrected and thickness-normalized R-SoXS profiles of films based on D18-CI:Y6, D18-CI:Y6:PC₆₁BM and D18-CI:Y6:PC₇₁BM blends, cast from fresh, 5-day-aged and 20-day-aged inks, acquired at 283.8 eV, are displayed respectively in FIGS. 2C, 11A, and 11B. As can be seen in FIG. 2C, the peak positions of D18-CI:Y6 blend films show a clearly decreasing trend as the ink ages, which corresponds to an increasing long period and thus larger domain size. We employed lognormal functions to fit the peaks and obtained the peak positions (see FIGS. 12A-12C). The binary system can be fit roughly with two lognormal peaks, indicating a hierarchical or multi-length scale morphology. For the film cast from fresh ink, two peaks are located at q=0.059 and 0.124 nm-1, corresponding to long periods of 106 nm and 50.6 nm, respectively. For devices cast from 5-day-aged ink, the two peaks are located at q=0.059 and 0.096 nm-1, corresponding to long periods of 106 and 65 nm, respectively. While for the film cast from 20-day-aged ink, the two peaks moved to q=0.053 and 0.082 nm-1, corresponding to long periods of 119 nm and 76 nm, respectively. The trends in domain size observed with R-SoXS should be attributed to the unfavorable molecular pre-aggregation of the inks as they age at room temperature. In contrast to the binaries, the R-SoXS profiles of the ternary blend films with PC₆₁BM from fresh and aged inks (FIG. 11A) are quite similar to each other and only one lognormal peak can be distinguished. The fitting is displayed in FIGS. 13A-13C and the peak positions are all estimated to be around 0.12 nm-1, corresponding to long periods of 52 nm. The R-SoXS profiles of the ternary blend films with PC₇₁BM from fresh and aged inks are shown in FIG. 11B and the fitting is shown in FIGS. 14A-14C. For the ternary films cast from both fresh and 5-day-aged inks, one peak is fit and located at q=0.130 nm-1, corresponding to a long period of 48 nm. And for the film cast from 20-day-aged ink, one lognormal peak can be fit to be q=0.146 nm-1, corresponding to long periods of 43 nm. Similar to PC₆₁BM, the ternary blends with PC₇₁BM can also benefit to small domains and suppress the polymer pre-aggregation during aging. A comparison of long periods is summarized in FIG. 2D. This indicates that the ternary blend with PCBM not only exhibits small domain sizes, which is favorable for charge generation, but also ink aging does not result in larger aggregates as a function of time as observed for the binary blend.

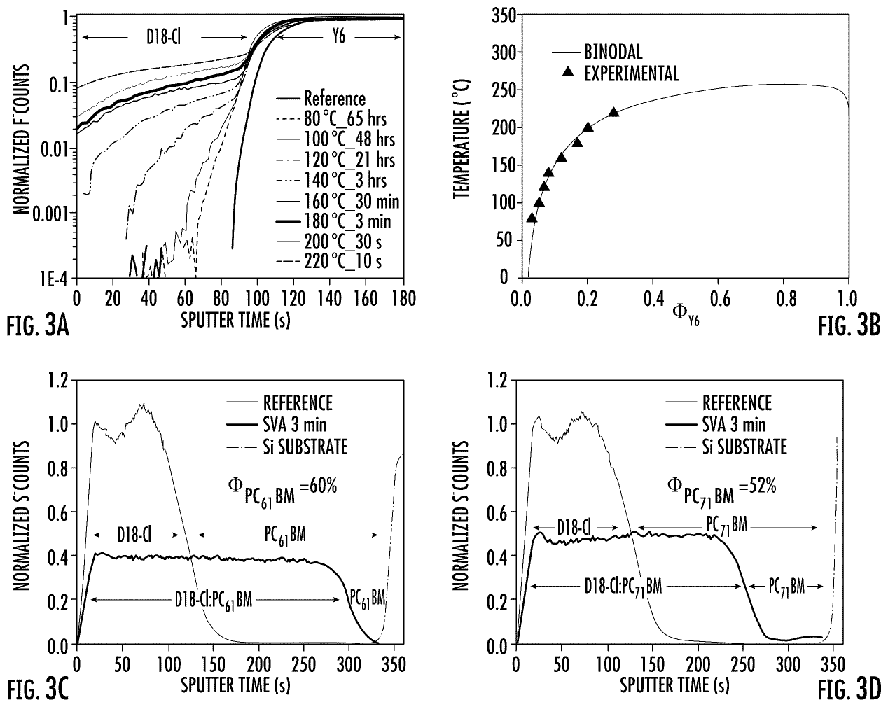

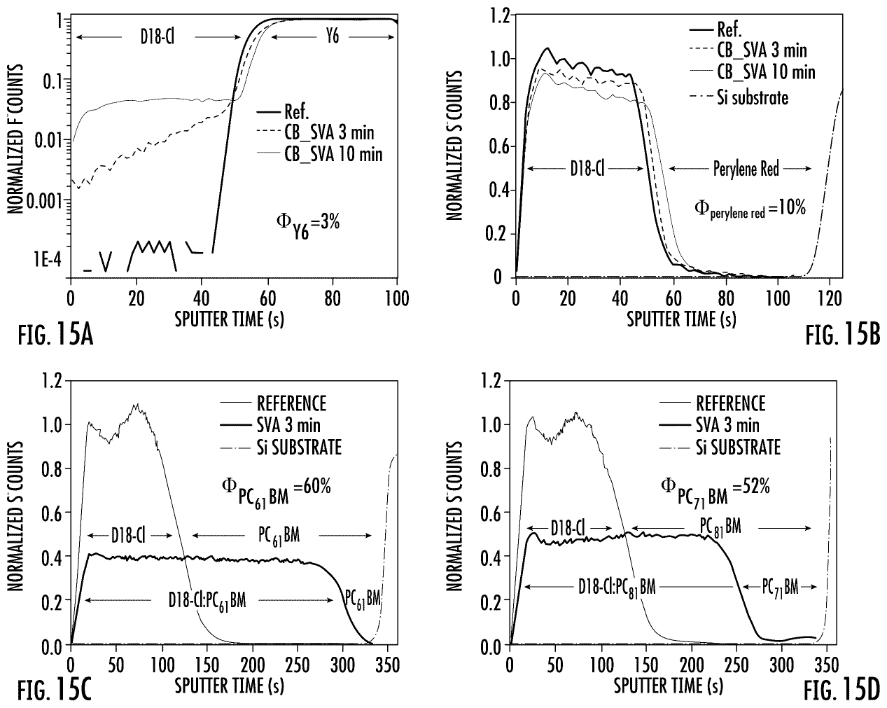

Though the R-SoXS results give us pretty clear mechanistic explanations of why the PCBMs could decelerate the ink aging, we delineate the thermodynamic nature of the binary and ternary systems to understand the molecular interactions that drive the observed improvements. To get more insights regarding the thermodynamic properties, time-of-flight secondary ion mass spectrometry (TOF-SIMS) was employed following prior established protocols to obtain the miscibility information between the donor and acceptor materials. FIG. 3A shows the TOF-SIMS profiles of D18-CI/Y6 bilayer samples annealed at different temperatures, tracking F-ion of the acceptor. And the corresponding miscibility information (Y6 fraction Φ_{Y6} as a function of temperature) of D18-CI/Y6 is shown in FIG. 3B along with a simulated binodal curve from the Flory-Huggins (FH) free energy of mixing equation for polymer inks with the actual molecular weights of the same system. As can be seen from the upper critical solution temperature (UCST) phase diagram, the polymer D18-CI and Y6 are hypo-miscible at low temperature (<150° C.), that is, the binodal composition is smaller than the percolation threshold, and the critical temperature is around 250° C. Using the FH fit, the miscibility of D18-CI:Y6 at room temperature (RT) is estimated by extrapolation to be Φ_{Y6 =}2.6%. This value is similar to the ˜3% derived by measurements on bilayers that were solvent vapor annealed (SVA) at RT with chlorobenzene (CB) (see FIG. 15A). This concentration is significantly below the percolation threshold that would maintain electron pathways and benefit the device performance. Even when devices are quenched to mixed domain composition that is near the percolation of ΦNFA=20%-30% when spin-casting from chloroform inks, this hypo-miscible nature of D18-CI/Y6 is likely to lead to over-purification of the morphology during aging of the devices and hence degrade the devices. At the same time, the strong repulsive interactions between D18-CI and Y6 makes Y6 a poor co-solvent in the ink.

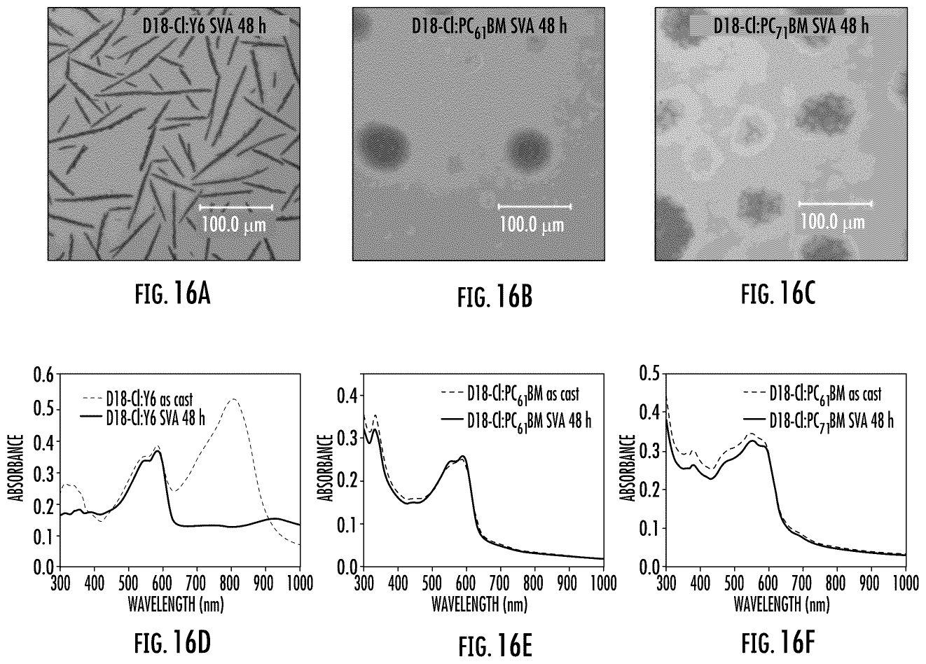

To assess qualitatively the relative co-solvent effect of fullerenes, we also measured the molecular interdiffusion for D18-CI/PC₆₁BM and D18-CI/PC₇₁BM bilayers that have been SVA with CB at RT to promote molecular diffusion. The corresponding mass-normalized profiles of D18-CI/PC₆₁BM and D18-CI/PC₇₁BM bilayers, tracking S-ion of the polymer, are shown in FIGS. 3C and 3D respectively. It is readily visible that the polymer layer swells due to the significant incorporation of the PCBM with a corresponding miscibility of D18-CI/PC₆₁BM is ΦPC₆₁BM ˜ 60% and the miscibility of D18-CI/PC₇₁BM is ΦPC₇₁BM ˜ 52% derived using prior protocols. See FIGS. 15C and 15D. Both the PCBM variants show hyper-miscibility with the polymer D18-CI. We note that the extensive swelling might have been restraint by tie-chains between paracrystallites, which would result in the measurements yielding a lower limit for the miscibility and the actually miscibility being even higher. We also attempted to utilize our previously developed UV-vis absorption method to verify the miscibility derived from the TOF-SIMS results (see FIGS. 16A-16F). Unfortunately, the density of PCBMs domains/crystals formed by SVA did not allow analysis. This lack of strong phase separation and lack of PCBM crystal formation contrasts to the observation in immiscible systems and confirms qualitatively the high miscibility of D18-CI:PCBMs that we observe quantitatively with TOFSIMS. Such high miscibility will maintain percolation and facilitate the flow of electrons from the acceptor phases through the mixed amorphous domains, consistent with prior works. Importantly, the high miscibility of the PCBM with D18-CI likely makes PCBM an effective co-solvent that suppresses the polymer aggregation in the solution.

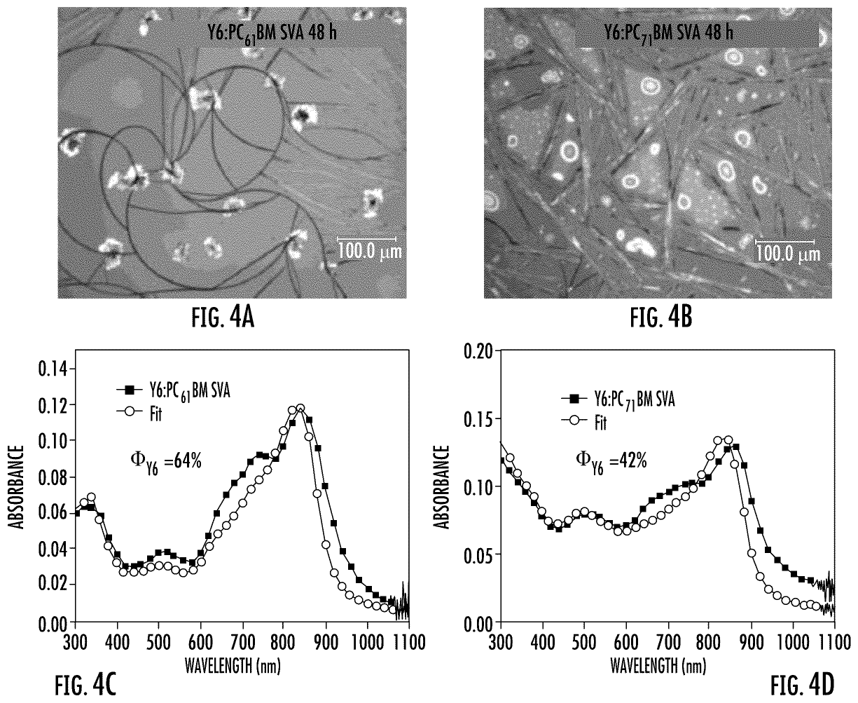

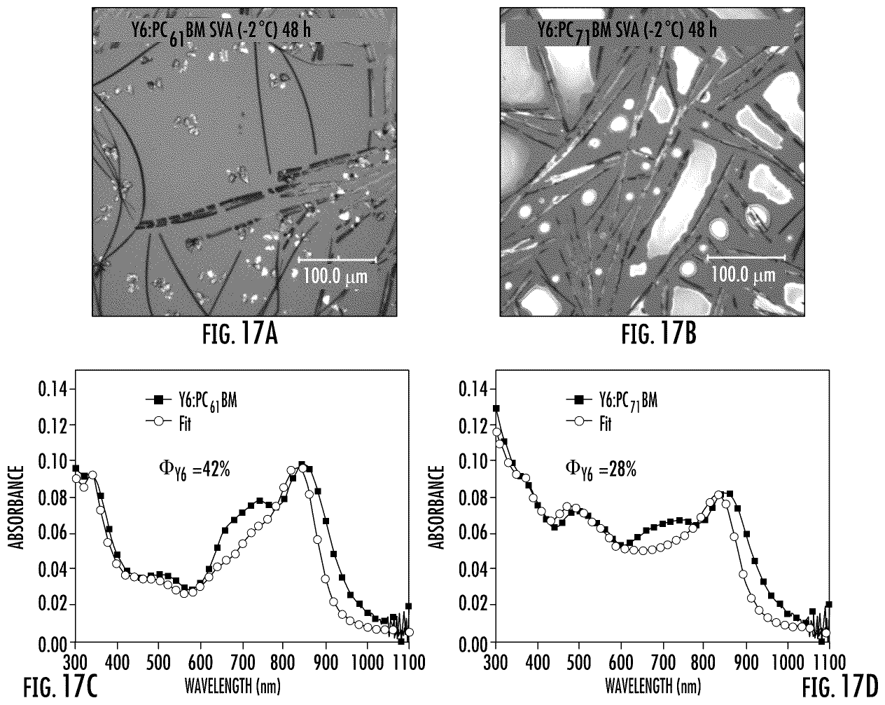

Due to the technical difficulty of floating small-molecule films on water, TOF-SIMS cannot be used to determine the Y6:PCBM miscibility. The UV-vis absorption method is then applied in this case, even though it does not yield the binodal but the liquidus composition. Due to added chemical potential of the crystals, only a lower limit of the miscibility can be derived. FIGS. 4A-4D shows visible light microscopy (VLM) images of Y6:PC₆₁BM, and Y6:PC₇₁BM blend films, SVA with CB for 48 hours at RT, and the corresponding UV-vis absorption spectra. By fitting the absorption spectra of annealed blend films with the mass-thickness corrected absorption spectra of the neat films, we can estimate the lower limit of the miscibility of Y6:PC₆₁BM to be Φ_{Y6}≈64% and the miscibility of Y6:PC₇₁BM to be Φ_{Y6}≈42%. When SVA at low temperature e.g. −2° C., the miscibility of Y6:PC₆₁BM is estimated to be Φ_{Y6}≈42% and the miscibility of Y6:PC₇₁BM is Φ_{Y6}≈28% (shown in FIGS. 17A-17D). The differences observed are consistent with an UCST phase diagram and indicate that the method measures meaningful relations. Furthermore, such high concentration of Y6 for the liquidus indicates that the critical temperature of the binodal is likely below room temperature and disordered Y6:PCBM are in the one-phase region at room temperature and intimately mixed.

In order to establish a control experiment, the small molecule perylene red (molecular structure is shown in FIG. 18) is introduced to D18-CI:Y6 system to modulate the molecular interactions between additive and binary components. TOF-SIMS characterization results of D18-CI/perylene red bilayers are shown in FIG. 15B along with the profiles of D18-CI/Y6, and D18-CI/PCBM bilayers for a clear comparison of the miscibilities. See FIGS. 15A, 15C, and 15D. Perylene red shows a miscibility of around 10% with D18-CI at room temperature, whereas the fullerenes had miscibilities >50%. Photovoltaic performance of D18-CI:Y6:perylene red devices fabricated from fresh and aged inks is summarized in Table 3, below. As a third component, perylene red could not reduce ink degradation during storage. The emerging proposed explanation is that small molecules that are highly miscible (>50%) with the polymer, i.e. PCBMs, can suppress the pre-aggregation and hence ink aging, while the additives, e.g. perylene red with small miscibility with the polymer can not. A similar argument will likely hold regarding a co-solvent effect for Y6.

TABLE 3
Summary of photovoltaic performance of D18-CI:Y6:Perylene
Red devices fabricated from fresh and aged inks.

| | | J_{SC} | | PCE_{avg} |
|---|---|---|---|---|
| Blends | V_{OC} (V) | (mA cm⁻²) | FF (%) | (%) |
| D18-CI:Y6:Perylene | 0.836 ± 0.010 | 22.12 ± 1.84 | 73.1 ± 1.6 | 13.54 ± 1.44 |
| Red fresh ink | | | | |
| D18-CI:Y6:Perylene | 0.822 ± 0.007 | 22.14 ± 0.10 | 63.2 ± 1.0 | 11.49 ± 0.20 |
| Red 5-day-aged ink | | | | |
| D18-CI:Y6:Perylene | 0.790 ± 0.009 | 21.77 ± 0.58 | 49.0 ± 0.7 | 8.43 ± 0.22 |
| Red 20-day-aged ink | | | | |

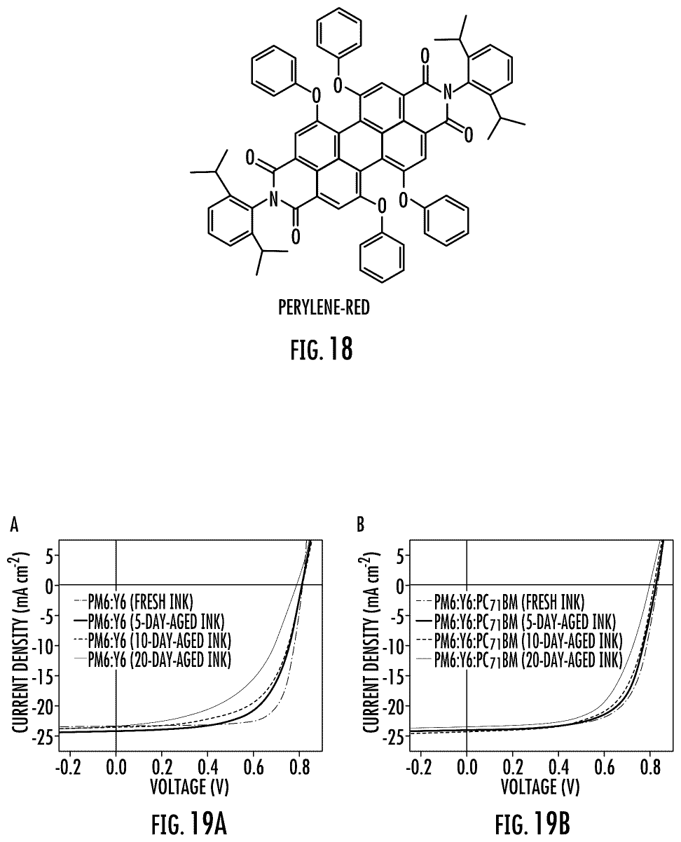

In a rudimentary confirmation of the co-solvent model, we turned to the PM6:Y6 system as PCBM has been previously shown to be highly miscible with PM6. Indeed, we found that the PM6:Y6 system behaves similarly to the D18-CI:Y6 system, with PC₇₁BM extending the ink shelf life. Corresponding photovoltaic performance is summarized in Table 4, below. The PM6:Y6 binary devices fabricated from fresh ink exhibit a PCE of 14.24% with an FF of 74.4%, and the binary devices fabricated from aged ink show a rapidly decreasing trend of PCE with the FF drops all the way down to only 51.4% when aged for 20 days. The PM6:Y6:PC₇₁BM ternary devices fabricated from fresh ink exhibit a PCE of 13.39% with an FF of 67.5%. Although the polymer batch utilized was not the best and devices were not extensively optimized, the trends are clear: Even though the performance of ternary devices fabricated from aged ink also decreases with the FF drops to 60.5%, the decrease is much smaller compared to the binaries. The different trends are easy to notice when comparing the J-V curves of the binary and ternary devices as shown in FIGS. 19A and 19B. The ability of PCBM to increase shelf life of the ink is consistent with our model that highly miscible additives prevent excessive aggregation.

TABLE 4
Summary of photovoltaic performance of PM6:Y6 and
PM6:Y6:PC₇₁ BM devices fabricated from fresh and aged inks.

| | | J_{SC} | | PCE_{avg} |
|---|---|---|---|---|
| Blends | V_{OC} (V) | (mA cm⁻²) | FF (%) | (%) |
| PM6:Y6 fresh ink | 0.810 ± 0.004 | 23.62 ± 0.13 | 74.5 ± 0.3 | 14.24 ± 0.11 |
| PM6:Y6 5-day-aged ink | 0.815 ± 0.005 | 24.00 ± 0.62 | 63.2 ± 0.9 | 12.36 ± 0.22 |
| PM6:Y6 10-day-aged ink | 0.816 ± 0.004 | 23.58 ± 0.24 | 60.5 ± 0.3 | 11.65 ± 0.16 |
| PM6:Y6 20-day-aged ink | 0.788 ± 0.004 | 22.96 ± 0.25 | 51.4 ± 0.6 | 9.30 ± 0.19 |
| PM6:Y6:PC₇₁BM fresh ink | 0.827 ± 0.003 | 24.00 ± 0.18 | 67.5 ± 0.9 | 13.39 ± 0.22 |
| PM6:Y6:PC₇₁BM 5-day-aged ink | 0.825 ± 0.006 | 23.52 ± 0.39 | 66.3 ± 0.4 | 12.86 ± 0.36 |
| PM6:Y6:PC₇₁BM 10-day-aged ink | 0.810 ± 0.003 | 24.15 ± 0.25 | 63.6 ± 0.3 | 12.44 ± 0.15 |
| PM6:Y6:PC₇₁BM 20-day-aged ink | 0.802 ± 0.003 | 23.22 ± 0.30 | 60.5 ± 1.5 | 11.28 ± 0.38 |

### CONCLUSION

In summary, aging of inks for polymer solar cells is a general issue that might prevent commercialization of OSCs. The aging of D18-CI:Y6 and PM6:Y6 inks were studied, and an approach to decelerate the ink degradation under storage with a highly miscible third component (PC₆₁BM or PC₇₁BM) is found effective and delineated. PCBMs are found to reduce the loss in PCE and especially the FF of the devices fabricated from aged inks. The control experiment with perylene red shows that it is indeed the high miscibility of PCBMs with the D18-CI and Y6 that is the likely causative thermodynamic parameter, which provides a co-solvent effect that suppresses the polymer and NFA pre-aggregation in the inks during storage and hence prevents the formation of large, detrimental domains in the thin films when devices are cast from aged inks. Also the PCBM can maintain percolation in the mixed-polymer domains that benefits the electron transport. This approach of introducing a hypermiscible third component to decelerate the ink aging is of great importance to lower the expense of larger area ink-printed organic solar cells and would be a step to their commercialization.

### Device Fabrication

The D18-CI-based solar cell devices were fabricated with conventional architecture of ITO/PEDOT: PSS/active-layer/PFN-Br/Ag. It is understood that OSC devices with the described subject matter can include any device architecture for OSCs known in the art. The effective device area is 0.075 cm² and the film thickness of the active layers is probed to be ˜100 nm. The hole-transporting layer PEDOT: PSS (AI 4083) was spin-cast onto the ITO glass at 4000 rpm, and then thermally treated at 150° C.° for 15 minutes. The inks for active layers were prepared in chloroform (CF) with a polymer concentration of 5 mg mL-1 and were stirred at 50° C. for 30 minutes to fully dissolve. The binary blend D18-CI:Y6 weight ratio was at 1:1.6 and that for the ternary blends D18-CI:Y6:PCBM was 1:1.6:0.2. After cooling down to room temperature, the inks of each blend were distributed into three glass vials respectively, two of which were sealed, wrapped with Al foil and stored in the glove box. For devices made from fresh ink, the ink was spin-cast on the PEDOT: PSS modified substrate at 3000 rpm (for binary) and 3200 rpm (for ternary). The samples were then put in a glass petri dish for solvent vapor annealing treatment. Around 50 μL CF was added into the petri dish and the samples was kept in for 5 minutes. Then the PFN-Br solution (1 mg mL-1 in methanol) was spin-cast onto the active layer as electron transporting layer at 3000 rpm. At last, 160 nm Ag was thermally evaporated to the samples with a rate of 1-2 Å s⁻¹, at ˜2×10⁻⁶ Pa. For devices made from aged inks, the aged inks were stirred for another 20 minutes before spin-casting, and the recipe was kept the same. We note that no matter the aged inks were stirred at room temperature or at warmer condition (e.g. 40-50° C.), the devices performance was fairly similar. This is consistent with our former work with D18 polymer (which is harder to process), where the inks cannot be restored and reused.

### Characterizations

The J-V characteristics were measured on a computer controlled Keithley 2400 source meter under illumination of an AM 1.5G solar simulator (Oriel Sol3A, Newport Corporation) with an intensity of 100 mW cm-2, which was calibrated by a certified silicon reference cell. The UV vis absorption spectra were recorded using a Varian Cary 50 UV-vis spectrophotometer. Transmission visible light microscopic (VLM) images are acquired with a Nikon Labophot-2 microscope. The film thicknesses were measured using a KLA Tencor (Model P-7) stylus profilometer.

### Grazing Incidence Wide Angle X-ray Scattering (GIWAXIS)

GIWAXS measurements were performed at beamline 7.3.3, Advanced Light Source (ALS), Lawrence Berkeley National Laboratory (LBNL). The samples were measured in a helium environment to minimize air scattering using 10 keV energy X-rays, which was incident at a grazing angle of 0.12°. The scattered X-rays were detected using a Pilatus 2M photon counting detector. The sample to detector distance was calibrated from diffraction peaks of the Silver-Behenate.

### Resonant Soft X-ray Scattering (R-SoXS)

R-SoXS measurements were performed at beamline 11.0.1.2, ALS, LBNL. The sample to detector distance was calibrated from diffraction peaks of polystyrene nanoparticles (diameter 300 nm) and beamline energy was calibrated by a fullerene-based sample. The beam size at the sample was ˜100 μm×200 μm, and 2D R-SoXS patterns were collected on an in-vacuum CCD camera (Princeton Instrument PI-MTE) at −45° C.

### Time-of-Flight Secondary Ion Mass Spectroscopy (TOF-SIMS) and Bilayer Fabrication

The TOF-SIMS experiments were conducted using a TOF-SIMS V (IONTOF Incorporation) instrument equipped with a Bi³⁺ charge compensation. Cs⁺ was used as the sputter source with a 10 keV energy and 20 nA current. The sputter area was 50×50 μm and sputter rate was approximately 1 nm s⁻¹. The analysis chamber pressure was maintained below 5×10⁻⁹ mbar to avoid contamination of the surfaces. Small molecule layers and polymer layers were made separately for bilayer samples. The small molecule films were spin-cast to ZnO modified Si substrate, and polymer films were spin-cast to PSS modified substrates and then float onto small molecule layers in water. Samples were dried and then moved into a glove box for thermal or solvent vapor annealing treatment.

The Hanson Solubility Parameters (HSP) are a combination of the following three components: δ_d, the dispersion component, δ_p the polar component, and δ_h the hydrogen-bonding component. The HSP for PCBM variants PC₆₁BM and PC₇₁BM are calculated as shown in Table 5, below

| | δ_d | δ_p | δ-h | δ |
|---|---|---|---|---|
| PCBM61 | 18.65 | 3.9 | 4.52 | 19.58 |
| PCBM71 | 18.71 | 3.75 | 4.43 | 19.59 |
| IEICO-4F | 19.32 | 2.03 | 4.42 | 19.92 |

Materials like IEICO-4F or another solvent with characteristics for total and similar HSP components similar to those of PCBM variants may be a good co-solvent to extend ink-stability and, therefore, could be used instead of or in addition to PCBM variants as additives to the binary polymer solar cell ink.

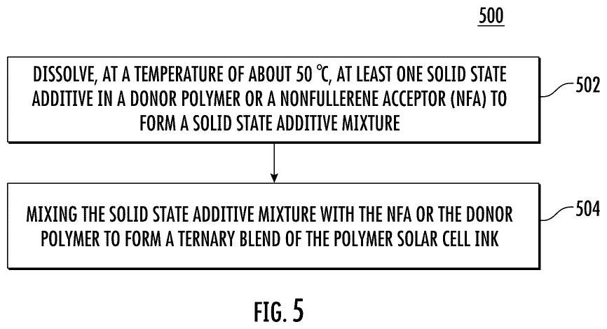

FIG. 5 is an example method 500 for preparing a polymer solar cell ink for organic solar cell (OSC) devices. At step 502, at least one solid state additive is dissolved in a donor polymer or a nonfullerene acceptor (NFA) at about 50° C. to form a solid state additive mixture. The at least one solid state additive can include at least one PCBM, such as PC₆₁BM and/or PC₇₁BM. The at least one PCBM can include a plurality of PCBM variants. The donor polymer can include D18-CI and the NFA can include Y6. An example composition by weight for D18-CI:Y6:PCBM is about 1:1.6:0.2. The donor polymer can include PM6 and the NFA can include Y6. The polymer solar cell ink can maintain a higher electron percolation than a polymer solar cell ink without the at least one solid state additive.

At step 504, the solid state additive mixture is mixed with the NFA or the donor polymer to form a ternary blend of the polymer solar cell ink. The ternary blend of the polymer solar cell ink can be formed into a layer to form an active layer for an OSC device.

The disclosure of each of the following references is incorporated herein by reference in its entirety.

### REFERENCES

1. Liu, Q., Jiang, Y., Jin, K., Qin, J., Xu, J., Li, W., Xiong, J., Liu, J., Xiao, Z., Sun, K., et al. (2020). 18% Efficiency organic solar cells. Sci. Bull. 65, 272-275.
2. Li, C., Zhou, J. D., Song, J. L., Xu, J. Q., Zhang, H. T., Zhang, X. N., Guo, J., Zhu, L., Wei, D. H., Han, G. C., et al. (2021). Non-fullerene acceptors with branched side chains and improved molecular packing to exceed 18% efficiency in organic solar cells. Nat. Energy 6, 605-613.
3. Wei, Y., Chen, Z., Lu, G., Yu, N., Li, C., Gao, J., Gu, X., Hao, X., Lu, G., Tang, Z., et al. (2022). Binary Organic Solar Cells Breaking 19% via Manipulating Vertical Component Distribution. Adv. Mater. 34, 2204718.
4. Cai, Y., Li, Y., Wang, R., Wu, H., Chen, Z., Zhang, J., Ma, Z., Hao, X., Zhao, Y., Zhang, C., et al. (2021). A Well-Mixed Phase Formed by Two Compatible Non-Fullerene Acceptors Enables Ternary Organic Solar Cells with Efficiency over 18.6%. Adv. Mater. 33, 2101733.
5. Bi, P., Zhang, S., Chen, Z., Xu, Y., Cui, Y., Zhang, T., Ren, J., Qin, J., Hong, L., Hao, X., et al. (2021). Reduced non-radiative charge recombination enables organic photovoltaic cell approaching 19% efficiency. Joule 5, 2408-2419.
6. Zhan, L., Li, S., Xia, X., Li, Y., Lu, X., Zuo, L., Shi, M., and Chen, H. (2021). Layer-by-Layer Processed Ternary Organic Photovoltaics with qEfficiency over 18%. Adv. Mater. 33, 2007231.
7. Zhao, Y., Wang, G., Wang, Y., Xiao, T., Adil, M. A., Lu, G., Zhang, J., and Wei, Z. (2019). A Sequential Slot-Die Coated Ternary System Enables Efficient Flexible Organic Solar Cells. Solar RRL 3, 1800333.
8. Yan, T., Song, W., Huang, J., Peng, R., Huang, L., and Ge, Z. (2019). 16.67% Rigid and 14.06% Flexible Organic Solar Cells Enabled by Ternary Heterojunction Strategy. Adv. Mater. 31, 1902210.
9. Wang, G., Zhang, J., Yang, C., Wang, Y., Xing, Y., Adil, M. A., Yang, Y., Tian, L., Su, M., Shang, W., et al. (2020). Synergistic Optimization Enables Large-Area Flexible Organic Solar Cells to Maintain over 98% PCE of the Small-Area Rigid Devices. Adv. Mater. 32, 2005153.
10. Chen, Z., Song, W., Yu, K., Ge, J., Zhang, J., Xie, L., Peng, R., and Ge, Z. (2021). Small-molecular donor guest achieves rigid 18.5% and flexible 15.9% efficiency organic photovoltaic via fine-tuning microstructure morphology. Joule 5, 2395-2407.
11. Zhang, Y., Liu, K., Huang, J., Xia, X., Cao, J., Zhao, G., Fong, P. W. K., Zhu, Y., Yan, F., Yang, Y., et al. (2021). Graded bulk-heterojunction enables 17% binary organic solar cells via nonhalogenated open air coating. Nat. Commun. 12, 4815.
12. Qin, F., Sun, L., Chen, H., Liu, Y., Lu, X., Wang, W., Liu, T., Dong, X., Jiang, P., Jiang, Y., et al. (2021). 54 cm² Large-Area Flexible Organic Solar Modules with Efficiency Above 13%. Adv. Mater. 33, 2103017.
13. Zhao, F., Zhang, H., Zhang, R., Yuan, J., He, D., Zou, Y., and Gao, F. (2020). Emerging Approaches in Enhancing the Efficiency and Stability in Non-Fullerene Organic Solar Cells. Adv. Energy Mater. 10, 2002746.
14. Moser, M., Wadsworth, A., Gasparini, N., and McCulloch, I. (2021). Challenges to the Success of Commercial Organic Photovoltaic Products. Adv. Energy Mater. 11, 2100056.
15. Zuo, G., Linares, M., Upreti, T., and Kemerink, M. (2019). General rule for the energy of water-induced traps in organic semiconductors. Nat. Mater. 18, 588-593.
16. Jiang, Y. Y., Sun, L. L., Jiang, F. Y., Xie, C., Hu, L., Dong, X. Y., Qin, F., Liu, T. F., Hu, L., Jiang, X. S., et al. (2019). Photocatalytic effect of ZnO on the stability of nonfullerene acceptors and its mitigation by SnO2 for nonfullerene organic solar cells. Mater. Horiz. 6, 1438-1443.
17. Liu, B., Han, Y., Li, Z., Gu, H., Yan, L., Lin, Y., Luo, Q., Yang, S., and Ma, C.-Q. (2020). Visible Light-Induced Degradation of Inverted Polymer: Nonfullerene Acceptor Solar Cells: Initiated by the Light Absorption of ZnO Layer. Solar RRL 5, 2000638.
18. Zhang, G., Hawks, S. A., Ngo, C., Schelhas, L. T., Scholes, D. T., Kang, H., Aguirre, J. C., Tolbert, S. H., and Schwartz, B. J. (2015). Extensive Penetration of Evaporated Electrode Metals into Fullerene Films: Intercalated Metal Nanostructures and Influence on Device Architecture. ACS Appl. Mater. Interfaces 7, 25247-25258.
19. Zheng, Z., He, E., Lu, Y., Yin, Y., Pang, X., Guo, F., Gao, S., Zhao, L., and Zhang, Y. (2021). Benzo [1,2-b: 4,5-b′] difuran Polymer-Based Non-Fullerene Organic Solar Cells: The Roles of Non-Fullerene Acceptors and Molybdenum Oxide on Their Ambient Stabilities and Processabilities. ACS Appl Mater Interfaces 13, 15448-15458.
20. Li, N., Perea, J.D., Kassar, T., Richter, M., Heumueller, T., Matt, G. J., Hou, Y., Güldal, N. S., Chen, H., Chen, S., et al. (2017). Abnormal strong burn-in degradation of highly efficient polymer solar cells caused by spinodal donor-acceptor demixing. Nat. Commun. 8, 14541.
21. Du, X., Heumueller, T., Gruber, W., Almora, O., Classen, A., Qu, J., He, F., Unruh, T., Li, N., and Brabec, C. J. (2020). Unraveling the Microstructure-Related Device Stability for Polymer Solar Cells Based on Nonfullerene Small-Molecular Acceptors. Adv. Mater. 32, 1908305.
22. Ghasemi, M., Hu, H., Peng, Z., Rech, J. J., Angunawela, I., Carpenter, J. H., Stuard, S. J., Wadsworth, A., McCulloch, I., You, W., et al. (2019). Delineation of Thermodynamic and Kinetic Factors that Control Stability in Non-fullerene Organic Solar Cells. Joule 3, 1328-1348.
23. Ghasemi, M., Balar, N., Peng, Z., Hu, H., Qin, Y., Kim, T., Rech, J. J., Bidwell, M., Mask, W., McCulloch, I., et al. (2021). A molecular interaction-diffusion framework for predicting organic solar cell stability. Nat. Mater. 20, 525-532.
24. Zhu, Y., Gadisa, A., Peng, Z., Ghasemi, M., Ye, L., Xu, Z., Zhao, S., and Ade, H. (2019). Rational Strategy to Stabilize an Unstable High-Efficiency Binary Nonfullerene Organic Solar Cells with a Third Component. Adv. Energy Mater. 9, 1900376.
25. Qin, Y. P., Balar, N., Peng, Z. X., Gadisa, A., Angunawela, I., Bagui, A., Kashani, S., Hou, J. H., and Ade, H. (2021). The performance-stability conundrum of BTP-based organic solar cells. Joule 5, 2129-2147.
26. Wang, Z., Peng, Z., Xiao, Z., Seyitliyev, D., Gundogdu, K., Ding, L., and Ade, H. (2020). Thermodynamic Properties and Molecular Packing Explain Performance and Processing Procedures of Three D18: NFA Organic Solar Cells. Adv. Mater. 32, 2005386.
27. Wang, T., and Brédas, J.-L. (2021). Organic Photovoltaics: Understanding the Preaggregation of Polymer Donors in Solution and Its Morphological Impact. J. Am. Chem. Soc. 143, 1822-1835.
28. Zeng, A., Ma, X., Pan, M., Chen, Y. Ma, R., Zhao, H., Zhang, J., Kim, H., Shang, A., Luo, S., et al. (2021). A Chlorinated Donor Polymer Achieving High-Performance Organic Solar Cells with a Wide Range of Polymer Molecular Weight. Adv. Funct. Mater. 31, 2102413.
29. Smilgies, D.-M. (2009). Scherrer grain-size analysis adapted to grazing-incidence scattering with area detectors. J. Appl. Crystallogr. 42, 1030-1034.
30. Carpenter, J. H., Hunt, A., and Ade, H. (2015). Characterizing morphology in organic systems with resonant soft X-ray scattering. J. Electron. Spectrosc. Relat. Phenom. 200, 2-14.
31. Collins, B. A., Li, Z., Tumbleston, J. R., Gann, E., McNeill, C. R., and Ade, H. (2013). Absolute Measurement of Domain Composition and Nanoscale Size Distribution Explains Performance in PTB7:PC₇₁BM Solar Cells. Adv. Energy Mater. 3, 65-74.
32. Ye, L., Hu, H., Ghasemi, M., Wang, T., Collins, B.A., Kim, J. H., Jiang, K., Carpenter, J. H., Li, H., Li, Z., et al. (2018). Quantitative relations between interaction parameter, miscibility and function in organic solar cells. Nat. Mater. 17, 253-260.
33. Kozub, D. R., Vakhshouri, K., Orme, L. M., Wang, C., Hexemer, A., and Gomez, E.D. (2011). Polymer Crystallization of Partially Miscible Polythiophene/Fullerene Mixtures Controls Morphology. Macromolecules 44, 5722-5726.
34. Ye, L., Li, S., Liu, X., Zhang, S., Ghasemi, M., Xiong, Y., Hou, J., and Ade, H. (2019). Quenching to the Percolation Threshold in Organic Solar Cells. Joule 3, 443-458.
35. Ro, H. W., Akgun, B., O'Connor, B. T., Hammond, M., Kline, R.J., Snyder, C. R., Satija, S. K., Ayzner, A. L., Toney, M. F., Soles, C. L., et al. (2012). Poly (3-hexylthiophene) and [6,6]-Phenyl-C61-butyric Acid Methyl Ester Mixing in Organic Solar Cells. Macromolecules 45, 6587-6599.
36. Peng, Z., Jiao, X., Ye, L., Li, S., Rech, J., You, W., Hou, J., and Ade, H. (2018). Measuring Temperature-Dependent Miscibility for Polymer Solar Cell Blends: An Easily Accessible Optical Method Reveals Complex Behavior. Chem. Mater. 30, 3943-3951.
37. Yuan, J., Zhang, Y., Zhou, L., Zhang, G., Yip, H.-L., Lau, T.-K., Lu, X., Zhu, C., Peng, H., Johnson, P. A., et al. (2019). Single-Junction Organic Solar Cell with over 15% Efficiency Using Fused-Ring Acceptor with Electron-Deficient Core. Joule 3, 1140-1151.
38. Hexemer, A., Bras, W., Glossinger, J., Schaible, E., Gann, E., Kirian, R., MacDowell, A., Church, M., Rude, B., and Padmore, H. (2010). A SAXS/WAXS/GISAXS Beamline with Multilayer Monochromator. J. Phys. Conf. Ser. 247, 012007.
39. Gann, E., Young, A. T., Collins, B.A., Yan, H., Nasiatka, J., Padmore, H. A., Ade, H., Hexemer, A., and Wang, C. (2012). Soft x-ray scattering facility at the Advanced Light Source with real-time data processing and analysis. Rev. Sci. Instrum. 83, 045110.

What is claimed is:

1. A polymer solar cell ink for organic solar cell (OSC) devices, the polymer solar cell ink comprising:
at least one solid state additive;
a donor polymer; and
a nonfullerene acceptor (NFA).

2. The polymer solar cell ink of claim 1 wherein the at least one solid state additive includes at least one PCBM.

3. The polymer solar cell ink of claim 2 wherein the at least one PCBM includes PC₆₁BM.

4. The polymer solar cell ink of claim 2 wherein the at least one PCBM includes PC₇₁BM.

5. The polymer solar cell ink of claim 2 wherein the at least one PCBM includes a plurality of PCBM variants.

6. The polymer solar cell ink of claim 2 wherein the donor polymer includes D18-CI and the NFA includes Y6.

7. The polymer solar cell ink of claim 6 comprising a ratio by weight of about 1:1.6:0.2 for D18-CI:Y6:PCBM.

8. The polymer solar cell ink of claim 2 wherein the donor polymer includes PM6 and the NFA includes Y6.

9. The polymer solar cell ink of claim 1 wherein the polymer solar cell ink maintains a higher electron percolation than a polymer solar cell ink without the at least one solid state additive.

10. An OSC device comprising an active layer including the polymer solar cell ink of claim 1.

11. A method for preparing a polymer solar cell ink for organic solar cell (OSC) devices, the method comprising:
dissolving, at a temperature of about 50° C., at least one solid state additive in a donor polymer or a nonfullerene acceptor (NFA) to form a solid state additive mixture; and
mixing the solid state additive mixture with the NFA or the donor polymer to form a ternary blend of the polymer solar cell ink.

12. The method of claim 11 wherein the at least one solid state additive includes at least one PCBM.

13. The method of claim 12 wherein the at least one PCBM includes PC₆₁BM.

14. The method of claim 12 wherein the at least one PCBM includes PC₇₁BM.

15. The method of claim 12 wherein the at least one PCBM includes a plurality of PCBM variants.

16. The method of claim 12 wherein the donor polymer includes D18-CI and the NFA includes Y6.

17. The method of claim 16 comprising a ratio by weight of about 1:1.6:0.2 for D18-CI:Y6:PCBM.

18. The method of claim 12 wherein the donor polymer includes PM6 and the NFA includes Y6.

19. The method of claim 12 wherein the polymer solar cell ink maintains a higher electron percolation than a polymer solar cell ink without the at least one solid state additive.

20. The method of claim 11 comprising forming a film of the ternary blend of the polymer solar cell ink to form an active layer for an OSC device.
